(19) United States
(12) Patent Application Publication
(10) Pub. No.: US 2010/0307787 A1
(43) Pub. Date: Dec. 9, 2010

(54) SLIDABLE-TYPE PORTABLE TERMINAL

(75) Inventors: Hiroaki Ohmori, Miyagi (JP); Hideo Nakanishi, Kanagawa (JP); Takeshi Yamaguchi, Kanagawa (JP); Akito Sakamoto, Kanagawa (JP); Yasunori Komukai, Miyagi (JP)

Correspondence Address: Seed Intellectual Property Law Group PLLC, 701 Fifth Avenue, Suite 5400, Seattle, WA, 98104, US

(73) Assignee: PANASONIC CORPORATION, Osaka (JP)

(21) Appl. No.: 12/865,352

(22) PCT Filed: Dec. 22, 2008
(86) PCT No.: PCT/JP2008/003902

§ 371 Date: Jul. 29, 2010

(30) Foreign Application Priority Data
Jan. 31, 2008 (JP) 2008-020757

(51) Int. Cl. H05K 5/02

(52) U.S. Cl. 174/51

(57) ABSTRACT

A slidable-type portable terminal has a first enclosure; a second enclosure; a first board arranged in the first enclosure; a second board arranged in the second enclosure; an antenna electrically connected to the first board; a connecting unit that electrically connects together the first board and the second board; a plurality of sliding units that slidably connects the first enclosure to the second enclosure; and a conductor for electrically connecting the connecting unit to one of the plurality of sliding units. The one of the plurality of sliding units is electrically connected to a ground of the connecting unit by means of the conductor.

### TECHNICAL FIELD

The present invention relates to a slidable-type portable terminal in which one enclosure slides with respect to the other enclosure.

### BACKGROUND ART

In a communication device, such as a portable phone in which one enclosure slides with respect to the other enclosure (hereinafter referred to as a “slidable-type portable terminal”), circuit boards in the respective enclosures are electrically connected together by means of a flexible cable. The flexible cable connects; for instance, an antenna provided in one enclosure, to a circuit board for signal processing purpose provided in the other enclosure.

At least a slide distance between the enclosures must be assured as a length of the flexible cable. Depending on a location of a connector on a circuit board to which a terminal of the flexible cable is to be connected, the flexible cable must be made further longer. However, when the flexible cable is long, a corresponding electrical length also becomes long. For this reason, variations arise in impedance characteristic of an antenna during sliding action, which in turn affects antenna performance.

Therefore, in a slidable-type portable phone described in connection with Patent Document 1, an intermediate portion of a flexible cable 10 interconnecting connector terminal areas 23A and 23B is electrically connected to an ground connection 25 connected to a ground layer of a substrate 17, as shown in FIG. 7. If the any point on the flexible cable 10 is connected to a ground as mentioned above, the electrical length of the flexible cable differs from a distance between the connector terminal areas 23A and 23B and changes to the length of the flexible cable from the ground area 25 to the connector terminal area 23B. Thus, since the electrical length can be shortened, the impedance characteristic of the antenna is enhanced.

Patent Document 1; JP-A-2006-93998

Patent Document 2; JP-A-2006-333387

Patent Document 3: JP-A-2006-203806

### DISCLOSURE OF THE INVENTION

### Problem that the Invention is to Solve

However, depending on locations of the connector terminal areas 23A and 23B, the slidable-type portable phone shown in FIG. 7 does not have any chance of addition of the ground area 25. Moreover, depending on locations of the connector terminal areas 23A and 23B, an appropriate location for the ground area 25 may not be available on the substrate 17.

Further, as shown in FIG. 8, in the slidable-type portable phone, a slider 15 connected to an enclosure 2 slidably fits to slide rails 12 provided in an enclosure 1; hence, the two enclosures 1 and 2 can slide each other. However, when the slide rails 12 are formed from a conductor, such as metal or depending on conditions of the ground in the enclosures, antenna gain cannot be significantly enhanced by a mere reduction in the electrical length that is accomplished by means of connecting the arbitrary point on the flexible cable 10 to the ground, as mentioned previously.

Specifically, in the slidable-type portable phone shown in FIG. 7, a coupling current that is opposite in phase to an antenna current flows into a portion of a ground layer of a circuit board 20 and a portion of a metal frame 21 through which the antenna current also flows, as shown in FIG. 9, as a result of an antenna 22 provided in the enclosure 2, the circuit board 20 provided in the enclosure 1, and the metal frame 21 being capacitively coupled together. The current having the opposite phase degrades a VSWR (Voltage Standing Wave Ratio) characteristic, which raises a problem of deterioration of the antenna gain.

An objective of the present invention is to provide a slidable-type portable terminal in which one enclosure slides with respect to the other enclosure and which achieves high antenna gain.

### Means For Solving the Problem

The present invention provides a slidable-type portable terminal comprising: a first enclosure; a second enclosure; a first board arranged in the first enclosure; a second board arranged in the second enclosure; an antenna electrically connected to the first board; a connecting unit that electrically connects together the first board and the second board; a plurality of sliding units that slidably connects the first enclosure to the second enclosure; and a conductor for electrically connecting the connecting unit to one of the plurality of sliding units, wherein the one of the plurality of sliding units is electrically connected to a ground of the connecting unit by means of the conductor.

In the slidable-type portable terminal, a sliding unit electrically unconnected to the connecting unit, among the plurality of sliding units, is electrically connected to a ground of the first board.

In the slidable-type portable terminal, the slidable unit and the connecting unit are electrically connected or the slidable unit and the first board are electrically connected together by way of a reactance element.

### Advantageous Effects of the Invention

In a slidable-type portable terminal of the present invention, antenna gain is improved.

### BRIEF DESCRIPTION OF THE DRAWINGS

FIG. 1 is a perspective view showing a slidable-type portable terminal of an embodiment.

FIG. 2 is a schematic view showing internal configurations of respective enclosures provided in the slidable-type portable terminal shown in FIG. 1.

FIG. 3 is a cross-sectional view of the slidable-type portable terminal in a closed state as shown in FIG. 1 and taken along line A-A shown in FIG. 2.

FIG. 4 is a diagrammatic view of an internal configuration of the slidable-type portable terminal shown in FIG. 1 acquired when viewed from its right side.

FIG. 5 is a schematic drawing showing a distribution of an antenna current and a coupling current resultant from capacitive coupling in the slidable-type portable terminal shown in FIG. 1.

FIG. 6 is a cross-sectional view of the slidable-type portable terminal in the closed state as shown in FIG. 1 and taken along line B-B shown in FIG. 2.

FIG. 7 is a cross sectional view of a slidable-type portable phone described in connection with Patent Document 1.

FIG. 8 is a perspective view showing one enclosure provided in the slidable-type portable phone shown in FIG. 7.

FIG. 9 is a schematic drawing showing a distribution of an antenna current and a coupling current resultant from capacitive coupling in the slidable-type portable phone shown in FIG. 7.

### DESCRIPTIONS OF THE REFERENCE NUMERALS AND SYMBOLS

100 UPPER ENCLOSURE

200 LOWER ENCLOSURE

101 CIRCUIT BOARD (UPPER BOARD)

201 CIRCUIT BOARD (LOWER BOARD)

103a, 103b RAIL

203a, 203b SLIDER

105, 205a, 205b SHEET-METAL

115, 215a, 215b SCREW

207 REACTANCE ELEMENT

209 BUILT-IN ANTENNA

301 FLEXIBLE CABLE

### BEST MODE FOR IMPLEMENTING THE INVENTION

An embodiment of the present invention is hereunder described by reference to the drawings. An embodiment described hereunder provides an explanation about a communication device in which one enclosure slides with respect to the other enclosure (hereinafter referred to as a “slidable-type portable terminal”), such as a portable phone.

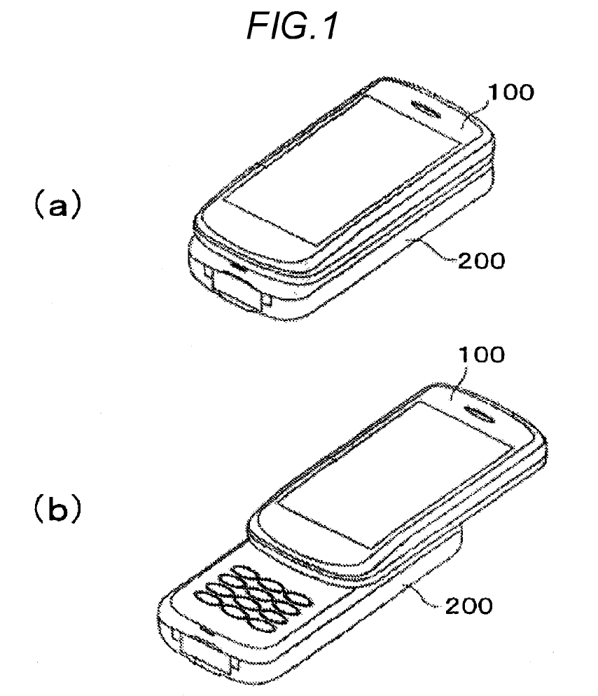

FIG. 1 is a perspective view showing a slidable-type portable terminal of an embodiment. In FIG. 1, (a) shows the slidable-type portable terminal in a closed state, and in FIG. 1, (b) shows the slidable-type portable terminal in an open state. The slidable-type portable terminal shown in FIG. 1 has an upper enclosure 100 and a lower enclosure 200 that are mutually slidable.

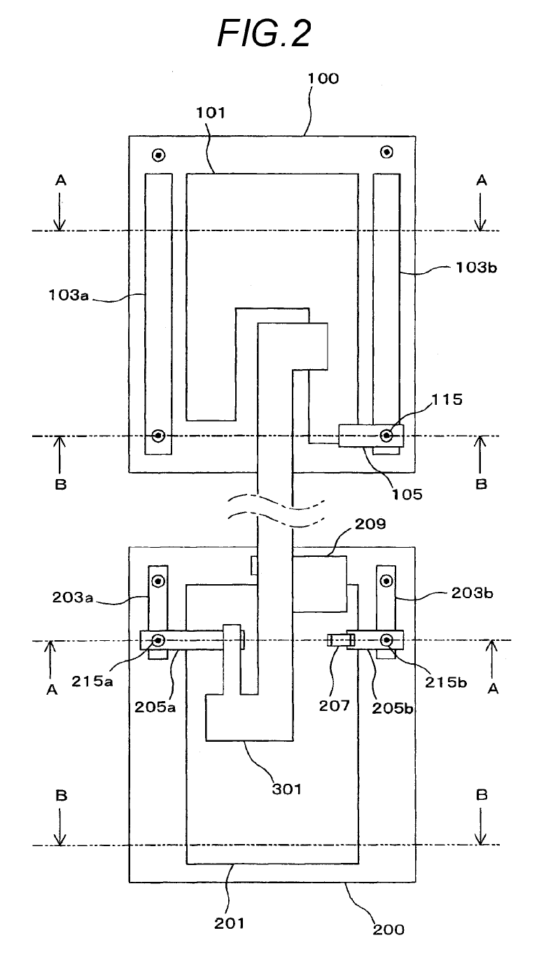

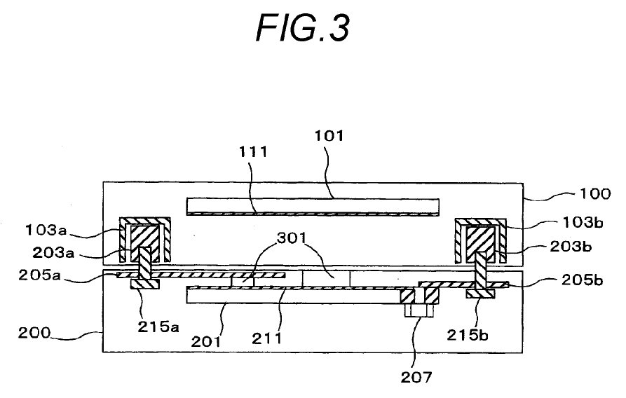

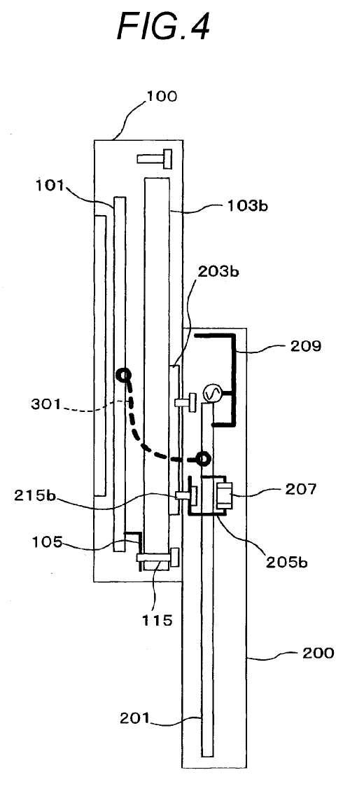

FIG. 2 is a schematic view showing internal configurations of respective enclosures provided in the slidable-type portable terminal shown in FIG. 1. FIG. 3 is a cross-sectional view of the slidable-type portable terminal in a closed state as shown in FIG. 1 and taken along line A-A shown in FIG. 2. FIG. 4 is a diagrammatic view of an internal configuration of the slidable-type portable terminal shown in FIG. 1 acquired when viewed from its right side.

As shown in FIGS. 2 through 4, the upper enclosure 100 has a circuit board (hereinbelow referred to as an “upper board”) 101, rails 103a and 103b, and a sheet-metal 105. The lower enclosure 200 has another circuit board (hereinafter referred to as a “lower board”) 201, sliders 203a and 203b, sheet-metals 205a and 205b, a reactance element 207, and a built-in antenna 209, such as a PIFA. As shown in FIG. 2, the upper board 100 of the upper enclosure 101 and the lower board 201 of the lower enclosure 200 are electrically connected to each other by means of a flexible flat cable (hereinafter referred to as a “flexible cable”) 301 whose length is equal to or greater than a slide length between the enclosures.

The rails 103a and 103b on the upper enclosure 100 are provided at right and left ends on a surface of the upper enclosure 100 that slides with respect to the lower enclosure 200; namely, a back side of the upper enclosure 100. The sliders 203a and 203b on the lower enclosure 200 are provided at right and left ends on a surface of the lower enclosure 200 that slides with respect to the upper enclosure 100; namely, a front side of the lower enclosure 200. Since the sliders 203a and 203b are slidably fitted into respective grooves of the rails 103a and 103b, the upper enclosure 100 and the lower enclosure 200 can slide with respect to each other. Incidentally, the rails 103a, 103b and the sliders 203a, 203b are formed from a conductor, such as metal.

In the embodiment, the sheet-metal 205a is screwed to one of the sliders (the slider 203a shown in FIGS. 2 and 3), whereby the slider 203a and a ground line of the flexible cable 301 are electrically connected to each other by way of the sheet-metal 205a and a screw 215a. The sheet-metal 205a and the screw 215a are formed from a conductor. The ground line of the flexible cable 301 is also connected to a ground layer 211 of the lower board 201 shown in FIG. 3. The slider 203a always remains in contact with the rail 103a. For this reason, the ground layer 211 of the lower board 201, the ground line of the flexible cable 301, the sheet-metal 205a, the screw 215a, the slider 203a, and the rail 103a are brought into electrical conduction, by means of forcing the slider 203a and the ground line of the flexible cable 301 into electrical conduction by way of the sheet-metal 205a and the screw 215a. Furthermore, the ground line of the flexible cable 301 connects the ground layer 211 of the lower board 201 to a ground layer 111 of the upper board 101. The ground layer 211 of the lower board 201, the ground line of the flexible cable 301, and the ground layer 111 of the upper board 101 are therefore in electrical conduction, as well. The rails and the sliders are not necessarily in DC conduction and may also be located in close proximity to each other to be in a capacitively coupled state.

The sheet-metal 205b is screwed to the other slider (the slider 203b shown in FIGS. 2 and 3), whereby the slider 203b and a ground layer 211 of the lower board 201 are electrically connected to each other by way of the sheet-metal 205b, the screw 215b, and the reactance element 207. The sheet-metal 205b and the screw 215b are formed from a conductor. The slider 203b remains in contact with the rail 103b at all times. Therefore, the ground layer 211 of the lower board 201, the reactance element 207, the sheet-metal 205b, the screw 215b, the slider 203b, and the rail 103b are brought into electrical conduction, by means of forcing the slider 203b and the ground layer 211 of the lower board 201 into electrical conduction by way of the sheet-metal 205b, the screw 215b, and the reactance element 207.

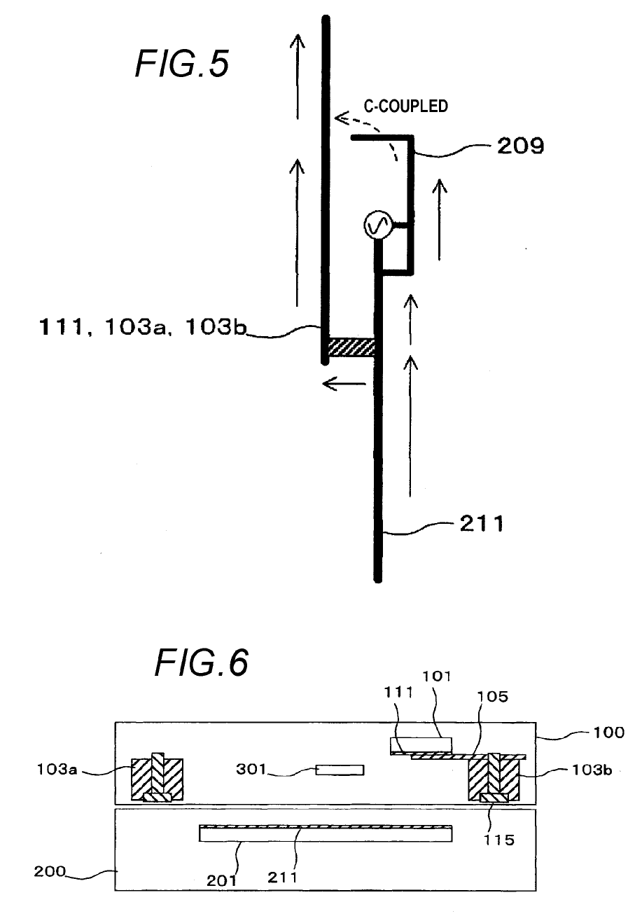

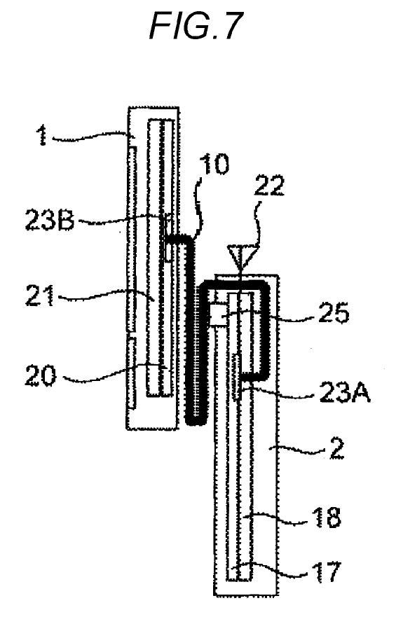

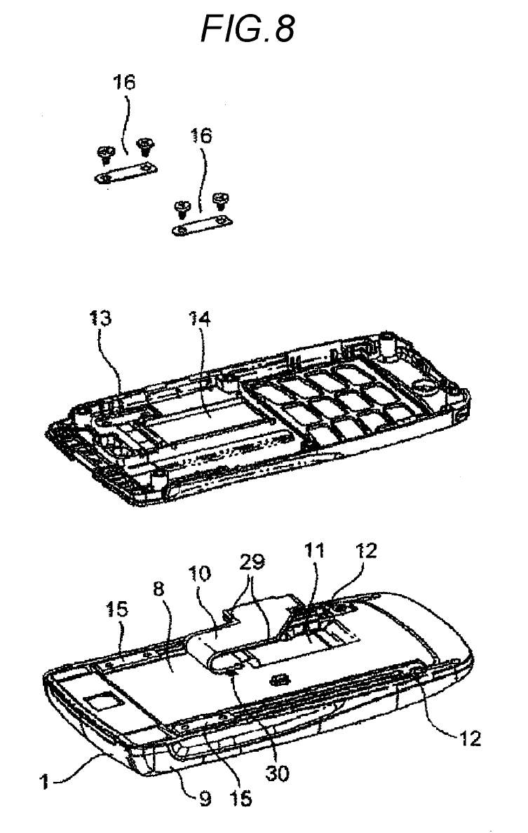

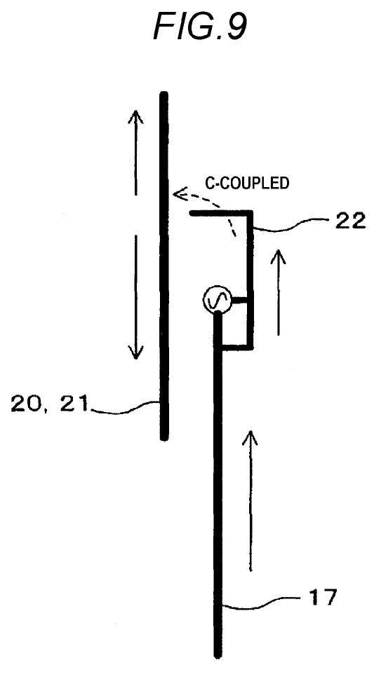

As mentioned above, in the embodiment, the rail 103a provided in the upper enclosure 100 remains in electrical conduction with the ground layer 211 of the lower board 201 of the lower enclosure 200 having the built-in antenna 209, by way of conductors such as the slider 203a, the ground line of the flexible cable 301, and the metal plate 205a. The rail 103b also remains in electrical conduction with the ground layer 211 of the lower board 201 by way of conductors such as the slider 203b and the sheet-metal 205a. In addition, the ground layer 111 of the upper board 101 is also in electrical conduction with the ground layer 211 of the lower board 201 by way of the ground line of the flexible cable 301. Therefore, as shown in FIG. 5, in the slidable-type portable terminal of the embodiment, even when the built-in antenna 209 of the lower enclosure 200, the rails 103a and 103b of the upper enclosure 100, and the ground line 111 of the upper board 101 are capacitively coupled together, the antenna current flowing through the ground layer 211 of the lower board 201 flows into the rails 103a, 103b and the ground layer 111 of the upper board 101. As a consequence, a distribution of the electric current in the rails 103a, 103b and the ground layer 111 of the upper board 101 becomes in phase with the antenna current, so that an enhanced VSWR characteristic and improved antenna gain are attained.

The reactance element 207 is interposed between the rail 103b and the ground layer 211 of the lower board 201. Insertion of the reactance element 207 enables changing of an impedance and the phase of the antenna current flowing into the upper board; therefore, antenna gain at a desired frequency band can be enhanced further. The reactance element 207 can be interposed between the slider 203a and the ground line of the flexible cable 301, too.

Furthermore, as shown in FIG. 2 and FIG. 6 that is a cross sectional view taken along line B-B shown in FIG. 2, at least one of the rails 103a and 103b (the rail 103b shown in FIGS. 2 and 6) can also be screwed to the sheet-metal 105. Further, the rail 103b and the ground layer 111 of the upper board 101 can be electrically connected to each other by way of the sheet-metal 105 and the screw 115, as well. The sheet-metal 105 and the screw 115 are conductors. The rail and the ground layer 111 of the upper board 101 are brought into electrical conduction, whereby constant grounding conditions are achieved by both the rails and the ground layer 111 of the upper board 101. Consequently, superior antenna gain can be stably acquired.

The embodiment has provided the descriptions about the method using the screw for electrical connection between the slider and the sheet-metal. However, the electrical connection is not limited to that method, and a connection employing a method using a conductive cushion, or the like, yields a similar advantage, so long as the method enables realization of an electrical connection between the slider and the sheet-metal.

The method for grounding the rails 103a, 103b and the upper board 101 also includes several conceivable methods, such as a connection made by a sheet-metal and a connection made by a conductive cushion. Moreover, insertion of a reactance element is also acceptable. A grounding location may also be a location between an upper end of the rail and the upper board 101, a location between a lower end of the rail and the upper board 101, one of both rails, and both of the rails.

The method for connecting the flexible cable 301 to the ground of the board may also be any of (1) a method for connecting the flexible cable 301 to the screw 215a and connecting the ground of the board to the screw 215b, (2) a method for connecting the flexible cable 301 to the screw 215b and connecting the ground of the board to the screw 215a, (3) a method for connecting the flexible cable 301 to both the screw 215a and the screw 215b, (4) a method for connecting the flexible cable 301 solely to the screw 215a, and (5) a method for connecting the flexible cable 301 solely to the screw 215b.

The upper enclosure 100 and the lower enclosure 200 employed in the previously-described embodiment correspond to a first enclosure and a second enclosure of claims. The upper board 101 and the lower board 201 also correspond to a first board and a second board, respectively. The rails 103a, 103b and the sliders 203a, 203b correspond to a plurality of sliding units. The sheet-metal 205a also corresponds to a conductor. Moreover, the flexible cable 301 corresponds to a connecting unit. The present invention is not limited to that described in connection with the embodiment and expected to be susceptible to alterations and applications contrived by the skilled in the art on the basis of the descriptions of the present patent application and well-known techniques. The alterations and applications shall fall within a range where protection of the present invention is to be sought.

Although the present invention has been described in detail and by reference to the specific embodiment, it is manifest to those skilled in the art that the present invention be susceptible to various alterations and modifications without departing the spirit and scope of the present invention.

The present patent application is based on Japanese Patent Application (Application No. 2008-20757) filed on Jan. 31, 2008, the entire subject matter of which is incorporated herein by reference.

### INDUSTRIAL APPLICABILITY

The slidable-type portable terminal of the present invention is useful as a communication device, such as a slidable-type portable phone having rails formed from a conductor and a slider formed from a conductor.

1. A slidable-type portable terminal comprising:
a first enclosure;
a second enclosure;
a first board arranged in the first enclosure;
a second board arranged in the second enclosure;
an antenna electrically connected to the first board;
a connecting unit that electrically connects together the first board and the second board;
a plurality of sliding units that slidably connects the first enclosure to the second enclosure; and
a conductor for electrically connecting the connecting unit to one of the plurality of sliding units, wherein
the one of the plurality of sliding units is electrically connected to a ground of the connecting unit by means of the conductor.

2. The slidable-type portable terminal according to claim 1, wherein a sliding unit electrically unconnected to the connecting unit, among the plurality of sliding units, is electrically connected to a ground of the first board.

3. The slidable-type portable terminal according to claim 1, wherein the one of the plurality of slidable units and the connecting unit are electrically connected or the one of the plurality of slidable units and the first board are electrically connected together by way of a reactance element.
